(19) United States
(12) Patent Application Publication
(10) Pub. No.: US 2024/0404927 A1
(43) Pub. Date: Dec. 5, 2024

(54) CERAMIC SUBSTRATE FOR POWER MODULE, METHOD FOR MANUFACTURING SAME, AND POWER MODULE HAVING SAME

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/697,199

(22) PCT Filed: Sep. 29, 2022
(86) PCT No.: PCT/KR2022/014661

§ 371 Date: Mar. 29, 2024

(30) Foreign Application Priority Data
Sep. 30, 2021 (KR) 10-2021-0129499

(51) Int. Cl. H01L 23/495; H01L 21/48; H01L 23/00; H01L 23/15; H01L 25/065

(52) U.S. Cl. CPC H01L 23/49575; H01L 21/4825; H01L 23/49513; H01L 23/49537; H01L 25/0655; H01L 23/15; H01L 24/32; H01L 24/33; H01L 2224/32245; H01L 2224/33181

(57) ABSTRACT

The present invention pertains to a ceramic substrate for a power module, a method for manufacturing same, and a power module having same. By forming a protruding electrode integrated with an electrode pattern, the ceramic substrate can improve electrical conductivity when bonded to an electrode of a semiconductor device, can stably convert rated voltage and current while eliminating electrical hazards that can occur during wire bonding, and can improve reliability and efficiency when used in high power applications.

### TECHNICAL FIELD

The present disclosure relates to a ceramic substrate for a power module, a method of manufacturing the same, and a power module including the ceramic substrate, and more particularly, to a ceramic substrate for a power module, which includes a protrusion type electrode bonded to an electrode of a semiconductor device, a method of manufacturing the same, and a power module including the ceramic substrate.

### BACKGROUND ART

A power module is a semiconductor module that has been optimized for the conversion or control of power by modulating a semiconductor device into a package.

The power module has a structure in which a substrate is placed on a base plate and a semiconductor device is placed on the substrate.

In the existing power module, a semiconductor device is electrically connected to a substrate by wire bonding made of gold (Au), copper (Cu), or aluminum (Al). The existing power module has a structure in which the substrate is also connected to a PCB by wire bonding. That is, the existing power module has a structure in which a power movement line for an electrical signal and power conversion is formed of wire bonding.

However, the wire bonding structure becomes a potential danger factor for the entire vehicle because the wire bonding structure has the possibility that a short circuit or a disconnection may occur due to high power and high current electrical energy, and has a difficulty in effectively dissipating heat generated from a semiconductor device. The contents described in the Background Art are to help the understanding of the background of the disclosure, and may include contents that are not a disclosed conventional technology.

### DISCLOSURE

### Technical Problem

The present disclosure has been contrived to solve the aforementioned problem, and an object of the present disclosure is to provide a ceramic substrate for a power module, which may be electrically connected to an electrode of a semiconductor device without a wire by a protrusion type electrode having a type that is integrated with an electrode pattern and may maximize heat dissipation efficiency, a method of manufacturing the same, and a power module including the ceramic substrate.

### Technical Solution

A method of manufacturing a ceramic substrate for a power module for achieving the aforementioned object according to an embodiment of the present disclosure may include bonding an electrode layer to at least one surface of a ceramic base, forming an electrode pattern by etching the electrode layer, and forming a protrusion type electrode in a remaining region of the electrode pattern except some region of the electrode pattern by half-etching the some region. The protrusion type electrode may be disposed to be bonded to an electrode of a semiconductor device.

In this case, the forming of the protrusion type electrode may include forming a photoresist on the electrode pattern, disposing, on the photoresist, a mask having a pattern corresponding to a region of the protrusion type electrode and then forming a photoresist pattern by exposing and developing the photoresist, half-etching some region of the electrode pattern in a thickness direction thereof by using the photoresist pattern as a mask, and removing the photoresist pattern.

Meanwhile, in the half-etching, a depth of the half-etching may be half of the thickness of the electrode pattern.

Meanwhile, the forming of the photoresist may include attaching a dry film photoresist on the electrode pattern.

Meanwhile, in the bonding of the electrode layer, the electrode layer may be subjected to annealing heat treatment so that thermal stress is removed from the electrode layer.

Furthermore, the bonding of the electrode layer may include disposing a brazing filler layer having a thickness of 5 μm or more to 100 μm or less between at least one surface of the ceramic base and the electrode layer by using any one method of paste coating, foil attachment, and a P-filler, and brazing-bonding the brazing filler layer by melting the brazing filler layer.

In the disposing of the brazing filler layer, the brazing filler layer may be made of a material including at least one of Ag, Cu, AgCu, and AgCuTi.

Meanwhile, a ceramic substrate for a power module according to an embodiment of the present disclosure is a ceramic substrate for a power module on which a plurality of semiconductor devices is mounted. The ceramic substrate may include a ceramic base, an electrode pattern formed on at least one surface of the ceramic base, and a plurality of protrusion type electrodes that protrude by some regions of the electrode pattern, which have been half-etched. The protrusion type electrode may be disposed to be bonded to an electrode of a semiconductor device. In this case, the thickness of the protrusion type electrode may be half of the thickness of the electrode pattern.

The electrode pattern may include a first electrode pattern formed on a top surface of the ceramic base and a second electrode pattern formed on a bottom surface of the ceramic base. The protrusion type electrode may include a plurality of first protrusion type electrodes that protrude by some regions of the first electrode pattern, which have been half-etched, and a plurality of second protrusion type electrodes that protrude by some regions of the second electrode pattern, which have been half-etched.

Meanwhile, the present disclosure may provide a power module including the ceramic substrate for a power module. Specifically, the power module may include a pair of ceramic substrates in each of which an electrode pattern has been formed in at least one surface of the ceramic base and a plurality of semiconductor devices disposed between the pair of ceramic substrates. Each of the pair of ceramic substrates may include a plurality of protrusion type electrodes that protrude by some regions of the electrode pattern, which have been half-etched. The protrusion type electrode provided in at least one of the pair of ceramic substrates may be bonded to an electrode of the semiconductor device. In this case, the thickness of the protrusion type electrode may be half of the thickness of the electrode pattern.

The electrode pattern may include a first electrode pattern formed on a top surface of the ceramic base and a second electrode pattern formed on a bottom surface of the ceramic base. The protrusion type electrode may include a plurality of first protrusion type electrodes that protrude by some regions of the first electrode pattern, which have been half-etched, and a plurality of second protrusion type electrodes that protrude by some regions of the second electrode pattern, which have been half-etched.

Meanwhile, in each of the pair of ceramic substrates, any one of the first protrusion type electrode and the second protrusion type electrode may be bonded to the electrode of the semiconductor device. Furthermore, in each of the pair of ceramic substrates, at least one of the first protrusion type electrode and the second protrusion type electrode may be formed to have an area corresponding to the electrode of the semiconductor device. Furthermore, the number of first protrusion type electrodes and the number of second protrusion type electrodes may be identical with each other.

### Advantageous Effects

According to the present disclosure, electrical conductivity can be improved upon bonding to the electrode of the semiconductor device, a rated voltage or current can be stably converted while removing an electrical danger factor which may occur upon wire bonding, and reliability and efficiency can be improved upon being used in high power because the protrusion type electrode having a type that is integrated with the electrode pattern is formed.

Furthermore, according to the present disclosure, heat dissipation efficiency can be improved because heat generated from the semiconductor device is easily transferred to the ceramic substrate through the protrusion type electrode.

Furthermore, according to the present disclosure, a heat dissipation characteristic can be maximized because heat generated from the semiconductor device can be dissipated from both surfaces of the semiconductor device through the protrusion type electrode formed in each of the pair of ceramic substrates although multiple and a large quantity of semiconductor devices are integrated in order to reduce the size of a power module.

### DESCRIPTION OF DRAWINGS

FIG. 1 is a perspective view illustrating a ceramic substrate for a power module according to an embodiment of the present disclosure.

FIG. 2 is a plan view illustrating the ceramic substrate for a power module according to an embodiment of the present disclosure.

FIG. 3 is a side view illustrating the ceramic substrate for a power module according to an embodiment of the present disclosure.

FIG. 4 is a side view illustrating the state in which a plurality of semiconductor devices has been bonded to the ceramic substrate for a power module in FIG. 3.

FIG. 5 is a side view illustrating an example in which the ceramic substrate for a power module according to an embodiment of the present disclosure has been disposed on both surfaces of a plurality of semiconductor devices.

FIG. 6 is a side view illustrating a ceramic substrate for a power module according to another embodiment of the present disclosure.

FIG. 7 is a side view illustrating an example in which the ceramic substrate for a power module according to another embodiment of the present disclosure has been disposed on both surfaces of a plurality of semiconductor devices.

FIG. 8 is a flowchart illustrating a method of manufacturing a ceramic substrate for a power module according to an embodiment of the present disclosure.

FIG. 9 is a perspective view illustrating an electrode pattern that is formed by etching an electrode layer that has been bonded to a ceramic base.

FIG. 10 is a cross-sectional view taken along line A-A′ in FIG. 9.

FIG. 11 is a flowchart illustrating a step of forming the protrusion type electrode.

FIG. 12 is a cross-sectional view illustrating the state in which a photoresist has been formed on the electrode pattern.

FIG. 13 is a cross-sectional view illustrating the state in which a mask has been disposed on the photoresist and exposed.

FIG. 14 is a cross-sectional view illustrating the state in which the exposed photoresist has been developed.

FIG. 15 is a cross-sectional view illustrating the state in which an electrode pattern in a region not including a photoresist pattern has been half-etched in a thickness direction thereof.

FIG. 16 is a cross-sectional view illustrating the state in which the photoresist pattern that remains has been removed.

### MODE FOR INVENTION

Hereinafter, preferred embodiments of the present disclosure will be described in detail with reference to the accompanying drawings.

Embodiments are provided to more fully explain the present disclosure to a person having ordinary knowledge in the art to which the present disclosure pertains. The following embodiments may be modified in various other forms, and the scope of the present disclosure is not limited to the following embodiments. Rather, these embodiments are provided to make the present disclosure more thorough and complete and to fully convey the spirit of the present disclosure.

Terms used in this specification are used to describe a specific embodiment, and are not intended to limit the present disclosure. Furthermore, in this specification, an expression of the singular number may include an expression of the plural number unless clearly defined otherwise in the context.

In the description of the embodiments, when it is described that each layer (film), area, pattern, or structure is formed “on” or “under” each substrate, layer (film), area, pad, or pattern, this includes both expressions, including that a layer is formed on another layer “directly” or “with a third layer interposed between the two layers (indirectly)”. Furthermore, a criterion for the term “on or under of each layer” is described based on the drawings.

The drawings are merely for enabling the spirit of the present disclosure to be understood, and it should not be interpreted that the scope of the present disclosure is limited by the drawings. Furthermore, in the drawings, a relative thickness or length or a relative size may be enlarged for convenience and the clarity of description.

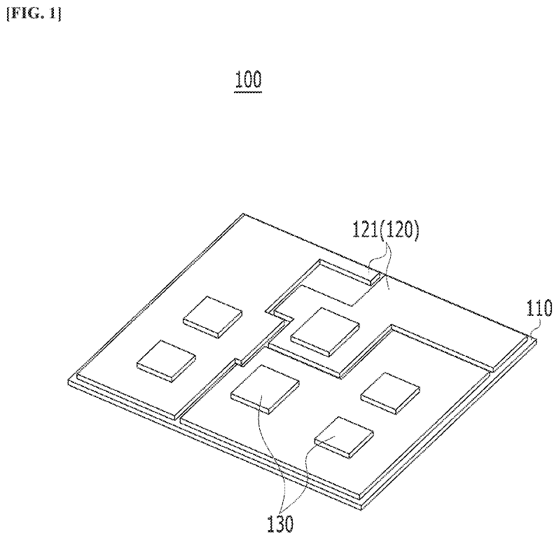

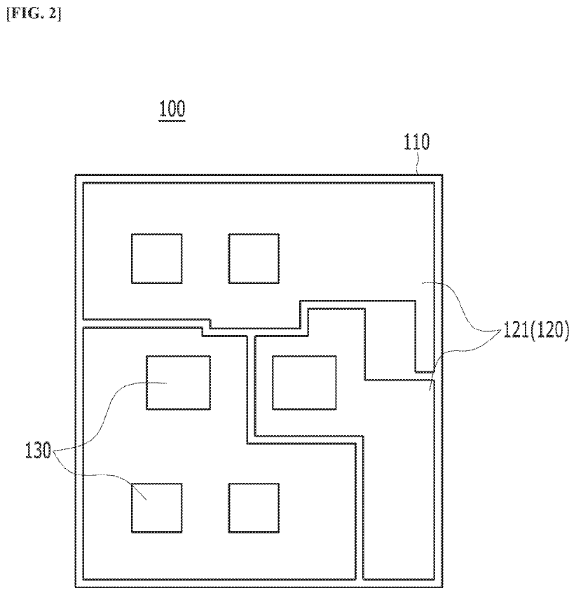

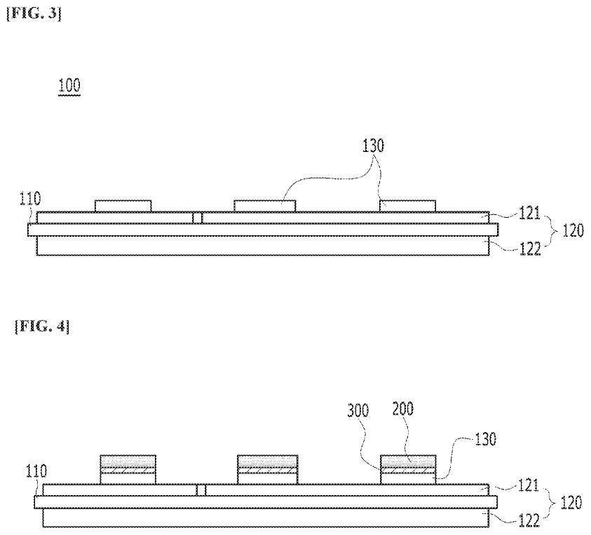

FIG. 1 is a perspective view illustrating a ceramic substrate for a power module according to an embodiment of the present disclosure. FIG. 2 is a plan view illustrating the ceramic substrate for a power module according to an embodiment of the present disclosure. FIG. 3 is a side view illustrating the ceramic substrate for a power module according to an embodiment of the present disclosure.

As illustrated in FIGS. 1 to 3, a ceramic substrate 100 for a power module according to an embodiment of the present disclosure may include a ceramic base 110, an electrode pattern 120, and a plurality of protrusion type electrodes 130. A plurality of semiconductor devices 200 may be mounted on the ceramic substrate to constitute a power module. Unlike in a conventional power module using wire bonding, in the power module of the present disclosure, electrodes (not illustrated) of the plurality of semiconductor devices 200 (refer to FIG. 4) are bonded to the plurality of protrusion type electrodes 130 of the ceramic substrate 100. Accordingly, a high-power and high-current electrical danger factor can be excluded and heat dissipation performance can be improved because wire bonding is omitted.

The ceramic base 110 may be any one of alumina (Al₂O₃), AlN, SiN, and Si₃N₄, for example. An electrode layer bonded to at least one surface of the ceramic base 110 may be formed as the electrode pattern 120 for mounting the semiconductor device or a surrounding part. For example, the electrode layer may be made of at least one of Cu, Al, AlSiC, CuMo, CuW, Cu/CuMo/Cu, Cu/Mo/Cu, and Cu/W/Cu or a composite material of them.

The electrode layer may be subjected to brazing bonding to at least one surface of the ceramic base 110, and may be formed as the electrode pattern 120 by being etched in accordance with a designed pattern. Such a substrate is called an active metal brazing (AMB) substrate. In the embodiment, the AMB substrate is described as an example, but a direct bonding copper (DBC) substrate or a thick printing copper (TPC) substrate may be applied. In this case, the AMB substrate is most suitable in terms of durability and heat dissipation efficiency.

The electrode layer may be subjected to brazing bonding to at least one surface of the ceramic base 110 through the medium of a brazing filler layer (not illustrated). The brazing filler layer may be made of a material including at least one of Ag, Cu, AgCu, and AgCuTi. The brazing filler layer may be formed as a thin layer having a multi-layer structure. For example, the brazing filler layer may be formed to have a 2-layer structure including an Ag layer and a Cu layer formed on the Ag layer. Alternatively, the brazing filler layer may be formed to have a 3-layer structure including a Ti layer, an Ag layer formed on the Ti layer, and a Cu layer formed on the Ag layer.

As illustrated in FIG. 3, the electrode pattern 120 may include a first electrode pattern 121 formed on a top surface of the ceramic base 110 and a second electrode pattern 122 formed on a bottom surface of the ceramic base 110.

The plurality of protrusion type electrodes 130 may protrude by some regions of the electrode pattern 120, which have been half-etched. The depth at which some region of the electrode pattern 120 is half-etched may be half of the thickness of the electrode pattern 120. In this case, the thickness of the protrusion type electrode 130, that is, the remaining region except the some region, may be half of the thickness of the electrode pattern 120.

The protrusion type electrode 130 may be disposed to be bonded to the electrode of the semiconductor device 200, and may be electrically connected to the semiconductor device 200. The area of the protrusion type electrode 130 may have a size of 0.5 mm or more and a thickness of 0.3 mm or more in accordance with the area of the electrode of the semiconductor device 200, but the present disclosure is not limited thereto.

FIG. 4 is a side view illustrating the state in which a plurality of semiconductor devices has been bonded to the ceramic substrate for a power module in FIG. 3.

As illustrated in FIG. 4, one surface of each of the plurality of protrusion type electrodes 130 may be bonded to the electrode of the semiconductor device 200 through the medium of a bonding layer 300. Although not illustrated, the protrusion type electrode 130 may be bonded to a gate electrode or source electrode of the semiconductor device 200, and thus may be electrically connected to the electrode of the semiconductor device 200.

The plurality of semiconductor devices 200 may each be at least one of an Si chip, an SiC chip, a GaN chip, a metal oxide semiconductor field effect transistor (MOSFET), an insulated gate bipolar transistor (IGBT), a junction field effect transistor (JFET), a high electric mobility transistor (HEMT), and a fast recovery diode (FRD).

For example, the electrode of an IGBT or SiC chip may be mounted on half of the plurality of protrusion type electrodes 130. An FRD device may be mounted on the remaining half of the plurality of protrusion type electrodes 130. Alternatively, a separate device is not mounted on the remaining half of the plurality of protrusion type electrodes 130, and the remaining half of the plurality of protrusion type electrodes may be used for heat dissipation or position fixing.

The bonding layer 300 is for bonding the electrode of the semiconductor device 200 and one surface of the protrusion type electrode 130, and may include a solder or Ag paste.

The solder may be composed of SnPb-based, SnAg-based, SnAgCu-based, or Cu-based solder paste having high bonding strength and excellent high temperature reliability. The Ag paste has more excellent high-temperature reliability and higher thermal conductivity than the solder. It is preferred that the Ag paste includes Ag powder of 90 to 99 weight % and a binder of 1 to 10 weight % so that thermal conductivity is high. It is preferred that the Ag powder is nano particles. The Ag powder of the nano particles has high bonding density and high thermal conductivity due to a large surface area.

As described above, in the ceramic substrate for a power module according to an embodiment of the present disclosure, the electrode pattern 120 may be formed by etching the electrode layer bonded to the ceramic base 110, and the protrusion type electrode 130 having a desired thickness may be formed by etching some region of the electrode pattern 120 again. The protrusion type electrode 130 may have improved electrical conductivity and an improved resistance characteristic because the protrusion type electrode has a type integrated with the electrode pattern 120 not separated from the protrusion type electrode. Furthermore, an air gap which may occur in a bonding surface upon bonding can be minimized because a spacer made of separate metal or a metal alloy does not need to be bonded by soldering, sintering, etc.

Furthermore, heat dissipation efficiency can be improved because heat generated from the semiconductor device 200 is transferred to the ceramic substrate 100 or a heat sink (not illustrated) combined with the ceramic substrate 100, through the protrusion type electrode 130.

FIG. 5 is a side view illustrating an example in which the ceramic substrate for a power module according to an embodiment of the present disclosure has been disposed on both surfaces of the plurality of semiconductor devices.

Referring to FIG. 5, the plurality of semiconductor devices 200 may be disposed between a pair of ceramic substrates 100A and 100B. The pair of ceramic substrates 100A and 100B may each include the ceramic base 110, the electrode pattern 120 formed on at least one surface of the ceramic base 110, and the plurality of protrusion type electrodes 130 that have protruded by some regions of the electrode pattern 120, which have been half-etched. The protrusion type electrode 130 of at least one of the pair of ceramic substrates 100A and 100B may be bonded and electrically connected to the electrode of the semiconductor device 200. For example, an electrode provided on a top surface of the semiconductor device 200 may be bonded and electrically connected to the protrusion type electrode 130 provided in an upper ceramic substrate 100A through the medium of the bonding layer 300. An electrode provided on a bottom surface of the semiconductor device 200 may be bonded and electrically connected to the protrusion type electrode 130 provided in a lower ceramic substrate 100B through the medium of the bonding layer 300. Alternatively, the electrode of the semiconductor device 200 may be provided only on the bottom surface and bonded to the protrusion type electrode 130 of the lower ceramic substrate 100B. In this case, the top surface of the semiconductor device 200 may be bonded to the protrusion type electrode 130 of the upper ceramic substrate 100A for heat dissipation. If a double-sided cooling type structure in which the pair of ceramic substrates 100A and 100B has been disposed on both surfaces of the plurality of semiconductor devices 200 as described above is applied, heat dissipation performance can be further improved.

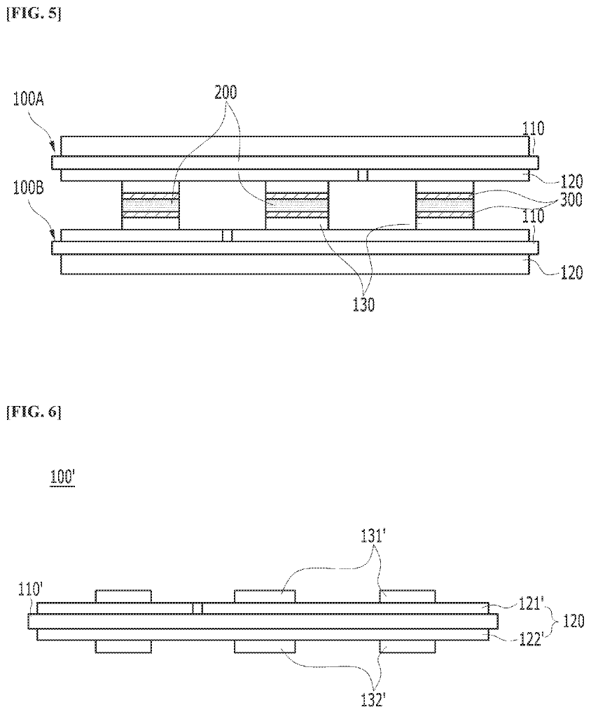

Hereinafter, a ceramic substrate for a power module according to another embodiment of the present disclosure is described with reference to FIGS. 6 to 8.

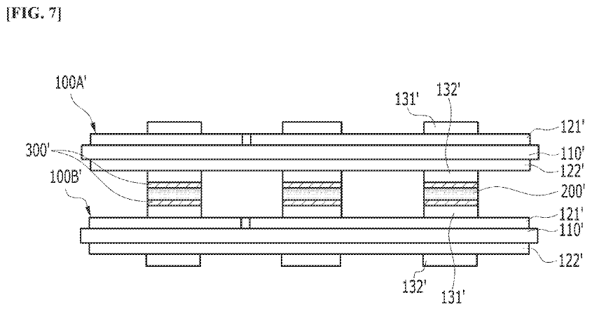

FIG. 6 is a side view illustrating a ceramic substrate for a power module according to another embodiment of the present disclosure. FIG. 7 is a side view illustrating an example in which the ceramic substrate for a power module according to another embodiment of the present disclosure has been disposed on both surfaces of a plurality of semiconductor devices.

Referring to FIG. 6, a ceramic substrate 100′ for a power module may include a first electrode pattern 121′ formed on a top surface of the ceramic base 110′ and a second electrode pattern 122′ formed on a bottom surface of the ceramic base 110′. Furthermore, the ceramic substrate 100′ may include a plurality of first protrusion type electrodes 131′ that protrude by some regions of the first electrode pattern 121′, which have been half-etched, and a plurality of second protrusion type electrodes 132′ that protrude by some regions of the second electrode pattern 122′, which have been half-etched.

In the ceramic substrate 100′ for a power module according to another embodiment of the present disclosure, the protrusion type electrodes 131′ and 132′ are provided on both surfaces of the ceramic substrate 100′ compared to the embodiment illustrated in FIGS. 1 to 5. If multiple and a large quantity of power semiconductor devices are integrated in order to reduce the size of a power module, a large amount of heat is generated. Accordingly, a heat dissipation characteristic can be maximized by applying a double-sided heat dissipation structure through the protrusion type electrodes 131′ and 132′ provided on both surfaces of the ceramic substrate 100′ of the present disclosure. The protrusion type electrodes 131′ and 132′ each having a type integrated with the electrode pattern 120 can effectively dissipate heat generated from the semiconductor device 200 because the protrusion type electrode may be made of at least one of Cu, Al, AlSiC, CuMo, CuW, Cu/CuMo/Cu, Cu/Mo/Cu, and Cu/W/Cu or a composite material thereof.

Referring to FIG. 7, a plurality of semiconductor devices 200′ may be disposed between the upper ceramic substrate 100A′ and the lower ceramic substrate 100B′. The upper ceramic substrate 100A′ and the lower ceramic substrate 100B′ may each include the same number of first protrusion type electrodes 131′ and the same number of second protrusion type electrodes 132′. An arrangement form of each of the first protrusion type electrode 131′ and the second protrusion type electrode 132′ is not limited to the form illustrated in the drawing. For example, the first protrusion type electrodes 131′ and the second protrusion type electrodes 132′ may be disposed at positions at which they have been dislocated with respect to each other or at positions at which they face each other on the basis of the ceramic base 110′ depending on their use.

Any one of the first protrusion type electrode 131′ and the second protrusion type electrode 132′ may be bonded to the electrode of the semiconductor device 200 and electrically connected to each of the pair of ceramic substrates 100A′ and 100B′. Furthermore, in each of the pair of ceramic substrates 100A′ and 100B′, at least one of the first protrusion type electrode 131′ and the second protrusion type electrode 132′ may be formed to have an area corresponding to the electrode of the semiconductor device 200′.

For example, the plurality of semiconductor devices 200′ may be disposed between the second protrusion type electrode 132′ of the upper ceramic substrate 100A′ and the first protrusion type electrode 131′ of the lower ceramic substrate 100B′. In this case, an electrode provided on a top surface of the semiconductor device 200′ may be bonded and electrically connected to the second protrusion type electrode 132′ provided in the upper ceramic substrate 100A′, through the medium of the bonding layer 300′. An electrode provided on a bottom surface of the semiconductor device 200′ may be bonded and electrically connected to the first protrusion type electrode 131′ of the lower ceramic substrate 100B′ through the medium of the bonding layer 300′. Alternatively, the electrode of the semiconductor device 200′ may be provided only on the bottom surface and bonded to the first protrusion type electrode 131′ of the lower ceramic substrate 100B′. In this case, the top surface of the semiconductor device 200′ may be bonded to the second protrusion type electrode 132′ of the upper ceramic substrate 100A′ for heat dissipation. If a double-sided cooling type structure in which the pair of ceramic substrates 100A′ and 100B′ has been disposed on both surfaces of the plurality of semiconductor devices 200′ as described above is applied, heat dissipation performance can be further improved.

Hereinafter, a method of manufacturing a ceramic substrate for a power module according to an embodiment of the present disclosure is described with reference to FIGS. 8 to 16.

As illustrated in FIG. 8, the method of manufacturing a ceramic substrate for a power module according to an embodiment of the present disclosure may include step S10 of bonding the electrode layer to at least one surface of the ceramic base 110, step S20 of forming the electrode pattern 120 by etching the electrode layer, and step S30 of forming the protrusion type electrode 130 in the remaining region of the electrode pattern 120 except some region thereof by half-etching the some region.

In step S10 of forming the electrode layer, the electrode layer made of metal may be bonded to at least one surface of the ceramic base 110 by an active metal brazing (AMB) process. The ceramic base 110 may be any one of alumina (Al₂O₃), ZTA, AlN, and Si₃N₄, for example. The electrode layer made of metal may be sintered at 780° C. to 1100° C., and may be subjected to brazing bonding to the top and bottom surfaces of the ceramic base 110. The substrate is called an active metal brazing (AMB) substrate. For example, the thickness of the ceramic base 110 may be 0.32 t, and the thickness of the electrode layer may be at least 0.3 mm or more.

In step S10 of bonding the electrode layer, the electrode layer may be other electrode material or metal alloy, such as Cu or Al. For example, the electrode layer may be made of at least one of Cu, Al, AlSiC, CuMo, CuW, Cu/CuMo/Cu, Cu/Mo/Cu, and Cu/W/Cu or a composite material thereof.

Furthermore, the electrode layer may be in the state in which the electrode layer has been subjected to annealing heat treatment and thermal stress has been removed from the electrode layer. A problem, such as bending, may occur in the electrode layer due to thermal stress in a process of the electrode layer being subjected to brazing bonding to the ceramic base 110 because the electrode layer has a great thickness corresponding to a thickness for forming the protrusion type electrode in subsequent etching processing. If thermal stress, thermal deformation, etc. are previously removed through annealing heat treatment before the electrode layer is subjected to brazing bonding to the ceramic base 110, thermal stress that occurs due to thermal expansion and thermal contraction in the brazing bonding process can be reduced. Furthermore, a bonding portion is not damaged and subsequent etching processing can be smoothly performed because the occurrence of bending of the electrode layer is minimized. A temperature, a time, etc. of the annealing heat treatment may be properly adjusted depending on a material of the electrode layer.

Step S10 of bonding the electrode layer may include a step of disposing the brazing filler layer having a thickness of 5 μm or more to 100 μm or less between at least one surface of the ceramic base and the electrode layer by using any one method of paste coating, foil attachment, and a P-filler and a step of brazing-bonding the brazing filler layer by melting the brazing filler layer.

In the step of disposing the brazing filler layer, the brazing filler layer may be made of a material including at least one of Ag, Cu, AgCu, and AgCuTi. The step of brazing-bonding the brazing filler layer by melting the brazing filler layer may be performed at 450° C. or more.

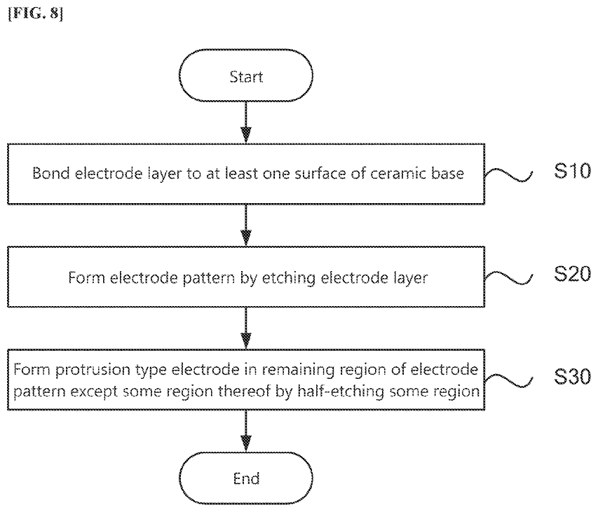

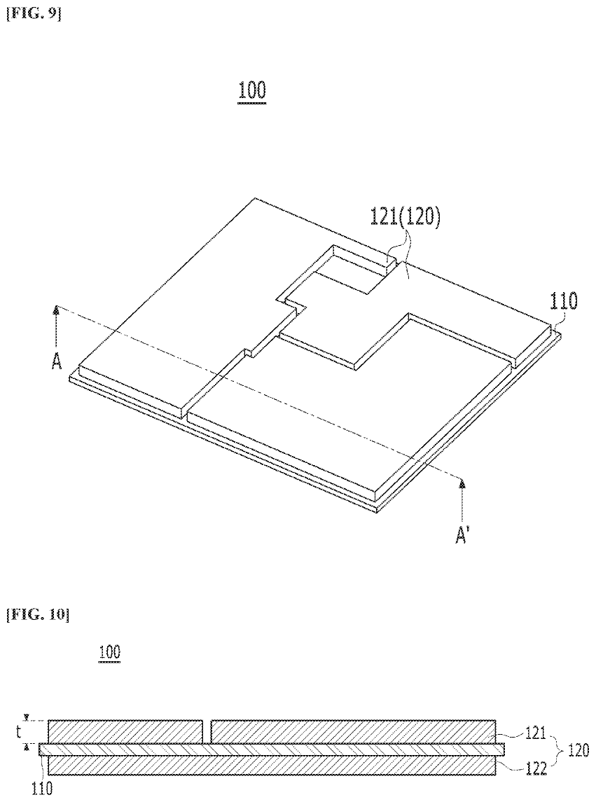

In step S20 of forming the electrode pattern 120, as illustrated in FIGS. 9 and 10, the electrode layer bonded to at least one surface of the ceramic base 110 may be formed as the electrode pattern 120 by etching the electrode layer in accordance with a designed pattern. For example, the electrode layer may be formed as the electrode pattern 120 on which a semiconductor device or a surrounding part may be mounted by a photolithography process. The electrode pattern 120 may include the first electrode pattern 121 formed on the top surface of the ceramic base 110 and the second electrode pattern 122 formed on the bottom surface of the ceramic base 110. For example, the thickness t of the first electrode pattern 121 may be 0.6 t, and the thickness of the second electrode pattern 122 may be 0.5 t.

Meanwhile, in step S30 of forming the protrusion type electrode 130, the protrusion type electrode 130 may be formed by half-etching some region of the electrode pattern 120 by a photolithography process. In this case, the protrusion type electrode 130 may be disposed to be bonded to the electrode of the semiconductor device 200.

As illustrated in FIG. 11, step S30 of forming the protrusion type electrode 130 may include step S31 of forming a photoresist 10 on the electrode pattern 120, step S32 of disposing, on the photoresist 10, a mask 20 having a pattern corresponding to the area of the protrusion type electrode 130 and then forming a photoresist pattern 11 by exposing and developing the photoresist, step S33 of half-etching some region of the electrode pattern 120 in a thickness direction thereof by using the photoresist pattern 11 as the mask, and step S34 of removing the photoresist pattern 11.

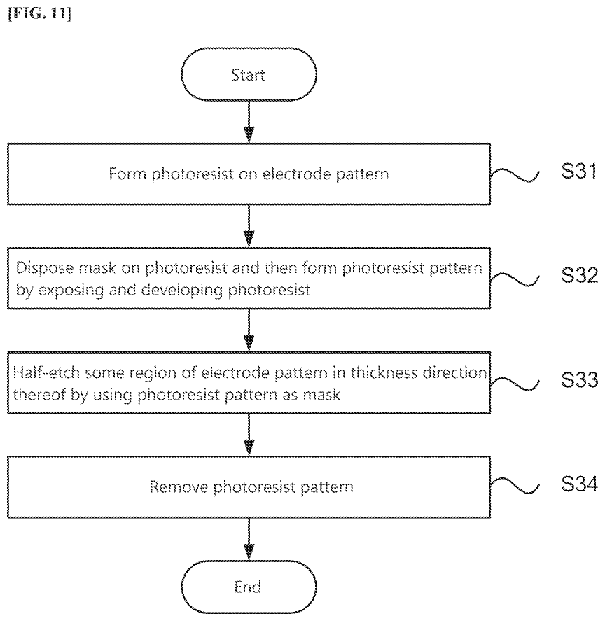

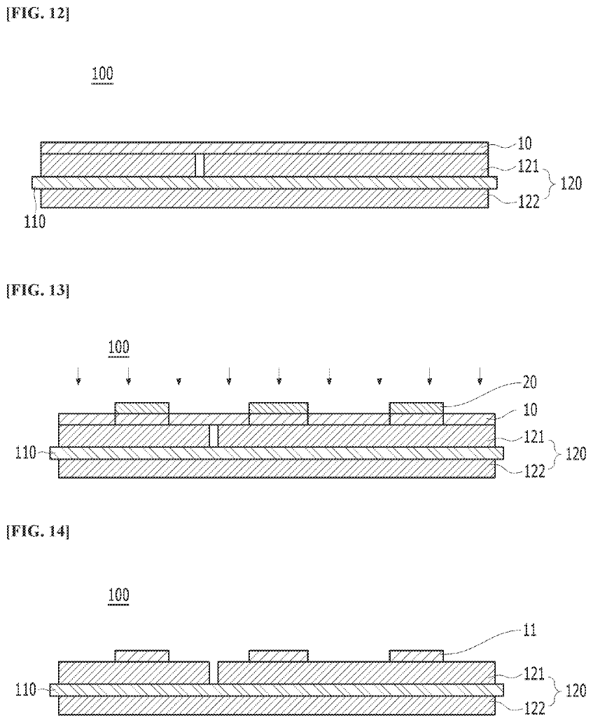

In step S31 of forming the photoresist 10, as illustrated in FIG. 12, the photoresist 10 may be formed to have a predetermined thickness on the electrode pattern 120. In this case, the photoresist 10 may be formed by attaching a dry film photoresist on the electrode pattern 120.

Step S32 of forming the photoresist pattern 11 may include a step of disposing, on the photoresist 10, the mask 20 having a pattern corresponding to the area of the protrusion type electrode 130 and then radiating a light source, such as ultraviolet (UV). As illustrated in FIG. 13, when the light source is radiated through the mask 20, a pattern formed on the mask 20 may be transferred to the photoresist 10. In this case, a type in which only a portion exposed by the light source is developed is a positive method. A type in which only a portion not exposed by the light source is developed is a negative method. In the present disclosure, an example in which the photoresist 10 using the positive method has been used is described, but the negative method may also be used.

Step S32 of forming the photoresist pattern 11 may include a step of developing the exposed photoresist 10. When the exposed photoresist 10 is developed, as illustrated in FIG. 14, only a photoresist in a region corresponding to the pattern of the mask 20 remains, so that the photoresist pattern 11 may be formed.

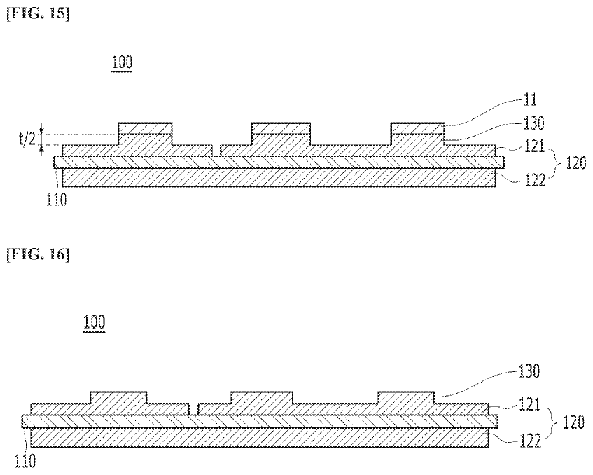

As illustrated in FIG. 15, in step S33 of half-etching, some region of the electrode pattern 120 in which the photoresist pattern 11 is not present may be half-etched in a thickness direction thereof by a process, such as dry etching or wet etching. In this case, the depth of the half-etching may be half (t/2) of the thickness of the electrode pattern 120. If some region of the electrode pattern 120 in which the photoresist pattern 11 is not present is half-etched by half the thickness by using the photoresist pattern 11 as a mask as described above, a region of the electrode pattern 120 in which the photoresist pattern 11 remains may more protrude than the peripheral region that has been half-etched. For example, when the thickness of the electrode pattern 120 is 0.6 t, the region of the electrode pattern 120 in which the photoresist pattern 11 is not present may be half-etched in the thickness direction thereof by 0.3 t, and the region of the electrode pattern 120 in which the photoresist pattern 11 remains may more protrude than the region that has been half-etched by 0.3 t.

As illustrated in FIG. 16, in step S34 of removing the photoresist pattern 11, the protrusion type electrode 130 may be finally formed by removing the photoresist pattern 11 that remains on the area of the protrusion type electrode 130.

As described above, in the method of manufacturing a ceramic substrate for a power module according to an embodiment of the present disclosure, the electrode pattern 120 may be formed by etching the electrode layer bonded to the ceramic base 110, and the protrusion type electrode 130 having a desired thickness may be formed by etching some region of the electrode pattern 120 again. Electrical conductivity can be improved and thus a resistance characteristic can be improved because the protrusion type electrode 130 has a type integrated with the electrode pattern 120 as described above. Furthermore, an air gap which may occur in a bonding surface upon bonding can be minimized because a spacer made of separate metal or a metal alloy does not need to be bonded by soldering, sintering, etc.

Furthermore, heat dissipation efficiency can be improved because heat generated from the semiconductor device 200 is transferred to the ceramic substrate 100, a heat sink (not illustrated) that is combined with the ceramic substrate 100, etc. through the protrusion type electrode 130.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A method of manufacturing a ceramic substrate for a power module, the method comprising:
bonding an electrode layer to at least one surface of a ceramic base;
forming an electrode pattern by etching the electrode layer; and
forming a protrusion type electrode in a remaining region of the electrode pattern except some region of the electrode pattern by half-etching the some region,
wherein the protrusion type electrode is disposed to be bonded to an electrode of a semiconductor device.

2. The method of claim 1, wherein the forming of the protrusion type electrode comprises:
forming a photoresist on the electrode pattern;
disposing, on the photoresist, a mask having a pattern corresponding to a region of the protrusion type electrode and then forming a photoresist pattern by exposing and developing the photoresist;
half-etching some region of the electrode pattern in a thickness direction thereof by using the photoresist pattern as a mask; and
removing the photoresist pattern.

3. The method of claim 2, wherein in the half-etching, a depth of the half-etching is half of the thickness of the electrode pattern.

4. The method of claim 2, wherein the forming of the photoresist comprises attaching a dry film photoresist on the electrode pattern.

5. The method of claim 1, wherein in the bonding of the electrode layer, the electrode layer is subjected to annealing heat treatment so that thermal stress is removed from the electrode layer.

6. The method of claim 1, wherein the bonding of the electrode layer comprises:
disposing a brazing filler layer having a thickness of 5 μm or more to 100 μm or less between at least one surface of the ceramic base and the electrode layer by using any one method of paste coating, foil attachment, and a P-filler; and
brazing-bonding the brazing filler layer by melting the brazing filler layer.

7. The method of claim 6, wherein in the disposing of the brazing filler layer, the brazing filler layer is made of a material comprising at least one of Ag, Cu, AgCu, and AgCuTi.

8. A ceramic substrate for a power module on which a plurality of semiconductor devices is mounted, the ceramic substrate comprising:
a ceramic base;
an electrode pattern formed on at least one surface of the ceramic base; and
a plurality of protrusion type electrodes that protrude by some regions of the electrode pattern, which have been half-etched,
wherein the protrusion type electrode is disposed to be bonded to an electrode of a semiconductor device.

9. The ceramic substrate of claim 8, wherein a thickness of the protrusion type electrode is half of a thickness of the electrode pattern.

10. The ceramic substrate of claim 8, wherein:
the electrode pattern comprises a first electrode pattern formed on a top surface of the ceramic base and a second electrode pattern formed on a bottom surface of the ceramic base, and
the protrusion type electrode comprises a plurality of first protrusion type electrodes that protrude by some regions of the first electrode pattern, which have been half-etched, and a plurality of second protrusion type electrodes that protrude by some regions of the second electrode pattern, which have been half-etched.

11. A power module comprising:
a pair of ceramic substrates in each of which an electrode pattern has been formed in at least one surface of the ceramic base; and
a plurality of semiconductor devices disposed between the pair of ceramic substrates,
wherein each of the pair of ceramic substrates comprises a plurality of protrusion type electrodes that protrude by some regions of the electrode pattern, which have been half-etched, and
the protrusion type electrode provided in at least one of the pair of ceramic substrates is bonded to an electrode of the semiconductor device.

12. The power module of claim 11, wherein a thickness of the protrusion type electrode is half of a thickness of the electrode pattern.

13. The power module of claim 11, wherein:
the electrode pattern comprises a first electrode pattern formed on a top surface of the ceramic base and a second electrode pattern formed on a bottom surface of the ceramic base, and
the protrusion type electrode comprises a plurality of first protrusion type electrodes that protrude by some regions of the first electrode pattern, which have been half-etched, and a plurality of second protrusion type electrodes that protrude by some regions of the second electrode pattern, which have been half-etched.

14. The power module of claim 13, wherein in each of the pair of ceramic substrates, any one of the first protrusion type electrode and the second protrusion type electrode is bonded to the electrode of the semiconductor device.

15. The power module of claim 13, wherein in each of the pair of ceramic substrates, at least one of the first protrusion type electrode and the second protrusion type electrode is formed to have an area corresponding to the electrode of the semiconductor device.

16. The power module of claim 13, wherein a number of first protrusion type electrodes and a number of second protrusion type electrodes are identical with each other.
